(19) United States
(12) Patent Application Publication
(10) Pub. No.: US 2011/0123796 A1
(43) Pub. Date: May 26, 2011

(54) INTERPOSER FILMS USEFUL IN SEMICONDUCTOR PACKAGING APPLICATIONS, AND METHODS RELATING THERETO

(75) Inventors: BRIAN C. AUMAN, Pickerington, OH (US); Thomas Edward Carney, Orient, OH (US); Kostantinos Kourtakis, Media, PA (US); Salah Boussaad, Wilmington, DE (US)

(73) Assignee: E.I. DUPONT DE NEMOURS AND COMPANY, Wilmington, DE (US)

(21) Appl. No.: 12/623,195

(22) Filed: Nov. 20, 2009

(51) Int. Cl. B32B 5/00; H05K 3/00

(52) U.S. Cl. 428/337; 427/96.1

(57) ABSTRACT

An interposer film for IC packaging is disclosed. The interposer film comprises a substrate that supports a plurality of electrically conductive domains. The substrate contains a rigid rod type polyimide and about 5-60 wt % filler. The filler has at least one dimension that (on average) is less than about 800 nanometers, and the filler also has an average aspect ratio greater than about 3:1.

### BACKGROUND OF THE INVENTION

1 Field of the Invention

The present disclosure relates generally to integrated circuit packaging. More specifically, the high performance polyimide films of the present disclosure are useful in ball grid array (BGA) or other semiconductor packaging configurations that utilize an interposer film.

2. Description of the Related Art

IC packaging technology is applied to IC chips: (1) to provide a path for the electrical current that powers the circuits on the chip; (2) to distribute the signals on to and off of the chip; (3) to remove the heat generated directly or indirectly by the IC chip; and (4) to support and protect the chip from hostile environments. A typical ball grid array (BGA) IC package includes an IC chip affixed to a flexible polyimide interposer film. In such BGA type IC packaging applications, a thin wire bond is used to connect a pad on the IC chip to a conductive trace on the polyimide interposer film. The conductive trace is routed to a solder ball. The solder ball is one of an array of solder balls mounted to the opposite side of the polyimide interposer film and protruding from the bottom of the BGA package. These solder balls interconnect with an array of pads located on a substrate, such as a printed circuit board. Accordingly, the typical BGA package electrically connects each pad on an IC to a pad on a printed circuit board.

In such packaging applications, processing temperatures can at times be very high, e.g., above 300° C. At such high operating temperatures the interposer film can exhibit dimensional distortion. Also, attempts to decrease processing costs can require reel-to-reel operations at increasingly higher tensions and such high tension processing can also cause an interposer film to exhibit dimensional distortion. A trend in the industry is toward less tolerance for dimensional distortion (exhibited by the interposer film), because the IC chip, the IC packaging and the associated circuitry is ever decreasing in size with every new generation in order to lower production costs. A need therefore exists in the industry from polyimide interposer films for IC packaging applications having improved thermal and dimensional stability.

U.S. Pat. No. 6,770,981 to Jiang et al. is directed to composite interposer films for BGA packaging applications.

### SUMMARY OF THE INVENTION

The interposer film compositions of the present disclosure for IC packaging applications comprise a filled polyimide substrate and a plurality of electrically conductive domains. The polyimide substrate has a thickness from about 8 to about 150 microns and contains from about 40 to about 95 weight percent of a polyimide derived from: i. at least one aromatic dianhydride, at least about 85 mole percent of such aromatic dianhydride being a rigid rod dianhydride, ii. at least one aromatic diamine, at least about 85 mole percent of such aromatic diamine being a rigid rod diamine. The polyimide substrates of the present disclosure further comprise a filler having primary particles (as a numerical average) that: i. are less than about 800 nanometers in at least one dimension; ii. have an aspect ratio greater than about 3:1; iii. are less than the thickness of the film in all dimensions; and iv. are present in an amount from about 5 to about 60 weight percent of the total weight of the substrate.

### BRIEF DESCRIPTION OF THE DRAWINGS

FIG. 1A shows a bottom view of a face-down, fan-in package employing an expansion lead, according to one embodiment of the present disclosure.

FIG. 1B shows a fragmentary cross-sectional view of a face-down, fan-in package employing an expansion lead, according to one embodiment of the present disclosure.

FIG. 1C shows a fragmentary cross-sectional view of a face-down, fan-in package employing an expansion lead having the leads on the second surface of the substrate, according to one embodiment of the present disclosure.

FIG. 1D shows a fragmentary cross-sectional view of a face-down, fan-in package employing an expansion lead wherein a compliant layer is disposed between the face surface of the chip and the first surface of the substrate, according to one embodiment of the present disclosure.

FIG. 2 is a perspective view of a pBGA package.

FIG. 3 is a cross-sectional view of a pBGA package.

FIG. 4 is a cross-sectional view of a preferred interposer of the present invention.

FIG. 5 is a cross-sectional view of a first level package being attached to a second level package.

FIG. 6 is a cross-sectional view of the first level package of FIG. 5, shown without the first level package case.

### DETAILED DESCRIPTION OF THE PREFERRED EMBODIMENT

### Definitions

“Electrically conductive domains” are intended to mean any conductive material, such as, conductive pads, conductive circuitry or traces, or the like. The electrically conductive domains are supported by the polymide films of the present disclosure. The electrically conductive domains provide, at least in part, the electrically conductive interface between the IC chip and subject matter that is not part of the IC chip. The electrically conductive interface allows: i. the IC chip to control (or influence) subject matter that is not part of the IC chip (e.g., circuitry on a printed wiring board, input/output devices or the like); and/or ii. allows control (or influence) upon the IC chip by subject matter that is not part of the IC chip (e.g., an electrical connection to power the IC chip).

“Film” is intended to mean a free-standing film or a coating on a substrate. The term “film” is used interchangeably with the term “layer” and refers to covering a desired area.

“Dianhydride” as used herein is intended to also include precursors and derivatives of (or otherwise compositions related to) dianhydrides, which may not technically be dianhydrides but are nevertheless functionally equivalent due to the capability of reacting with a diamine to form a polyamic acid which in turn could be converted into a polyimide.

Similarly, “diamine” is intended to also include precursors and derivatives of (or otherwise compositions related to) diamines, which may not technically be diamines but are nevertheless functionally equivalent due to the capability of reacting with a dianhydride to form a polyamic acid which in turn could be converted into a polyimide.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, articles “a” or “an” are employed to describe elements and components of the invention. This is done merely for convenience and to give a general sense of the invention. This description should be read to include one or at least one and the singular also includes the plural unless it is obvious that it is meant otherwise.

The embodiments described herein particularly relate to a polyimide interposer layer connecting a die to a solder ball array in a pBGA package. However, it will be appreciated that the principles of the present disclosure pertain not only to pBGA technology, but also to any IC packaging system utilizing an interposer layer. The interposer layers of the present disclosure are well adapted for any IC packaging technology utilizing an interposer layer in roll-to-roll or reel-to-reel processing.

The interposer films of the present disclosure resist shrinkage or creep (even under tension, such as, reel to reel processing) within a broad temperature range, such as, from about room temperature to temperatures in excess of 400° C., 425° C. or 450° C. In one embodiment, the interposer film of the present disclosure changes in dimension by less than 1, 0.75, 0.5, or 0.25 percent when subjected to a temperature of 450° C. for 30 minutes while under a stress in a range from 7.4-8.0 MPa (mega Pascals).

The polyimide interposer films of the present disclosure can be reinforced with thermally stable, inorganic: fabric, paper (e.g., mica paper), sheet, scrim or combinations thereof. In some embodiments, the interposer films of the present disclosure provide:
i. low surface roughness, i.e., an average surface roughness
(Ra) of less than 1000, 750, 500, 400, 350, 300 or 275 nanometers;
ii. low levels of surface defects; and/or
iii. other useful surface morphology, to diminish or inhibit unwanted defects, such as, electrical shorts.

In one embodiment, the interposer films of the present disclosure have an in-plane CTE in a range between (and optionally including) any two of the following: 1, 5, 10, 15, 20, and 25 ppm/° C., where the in-plane coefficient of thermal expansion (CTE) is measured between 50° C. and 350° C. In some embodiments, the CTE within this range is further optimized to further diminish or eliminate unwanted cracking due to thermal expansion mismatch of any particular supported semiconductor material selected in accordance with the present disclosure. Generally, when forming the polyimide, a chemical conversion process (as opposed to a thermal conversion process) will provide a lower CTE polyimide film. This is particularly useful in some embodiments, as very low CTE (<10 ppm/° C.) values can be obtained, closely matching those of the delicate conductor and semiconductor layer deposited thereon. Chemical conversion processes for converting polyamic acid into polyimide are well known and need not be further described here. The thickness of a polyimide interposer film can also impact CTE, where thinner films tend to give a lower CTE (and thicker films, a higher CTE), and therefore, film thickness can be used to fine tune film CTE, depending upon any particular application selected.

The films of the present disclosure have a thickness in a range between (and optionally including) any of the following thicknesses (in microns): 4, 6, 8, 10, 12, 15, 20, 25, 50, 75, 100, 125 and 150 microns. Monomers and fillers within the scope of the present disclosure can also be selected or optimized to fine tune CTE within the above range. Ordinary skill and experimentation may be necessary in fine tuning any particular CTE of the polyimide films of the present disclosure, depending upon the particular application selected. The in-plane CTE of the polyimide film of the present disclosure can be obtained by thermomechanical analysis utilizing a TA Instruments TMA-2940 run at 10° C./min, up to 380° C., then cooled and reheated to 380° C., with the CTE in ppm/° C. obtained during the reheat scan between 50° C. and 350° C.

The polyimide interposer films of the present disclosure should have high thermal stability so the films do not substantially degrade, lose weight, have diminished mechanical properties, or give off significant volatiles, e.g., during the semiconductor deposition process. The polyimide interposer films of the present disclosure should be thin enough to not add excessive weight or cost, but thick enough to provide high electrical insulation at operating voltages, which in some cases may reach 400, 500, 750 or 1000 volts or more.

In accordance with the present disclosure, a filler is added to the polyimide film to increase the polyimide storage modulus. In some embodiments, the filler of the present disclosure will maintain or lower the coefficient of thermal expansion (CTE) of the polyimide layer while still increasing the modulus. In some embodiments, the filler increases the storage modulus above the glass transition temperature (Tg) of the polyimide film. The addition of filler typically allows for the retention of mechanical properties at high temperatures and can improve handling characteristics. The fillers of the present disclosure:
1 have a dimension of less than 800 nanometers (and in some embodiments, less than 750, 650, 600, 550, 500, 475, 450, 425, 400, 375, 350, 325, 300, 275, 250, 225, or 200 nanometers) in at least one dimension (since fillers can have a variety of shapes in any dimension and since filler shape can vary along any dimension, the “at least one dimension” is intended to be a numerical average along that dimension);

2. have an aspect ratio greater than 3, 4, 5, 6, 7, 8, 9, 10, 11, 12, 13, 14, or 15 to 1 ;
3. is less than 100, 95, 90, 85, 80, 75, 70, 65, 60, 55, 50, 45, 40, 35, 30, 25, 20, 15 or 10 percent of the thickness of the film in all dimensions; and
4. is present in an amount between and optionally including any two of the following percentages: 5, 10, 15, 20, 25, 30, 35, 40, 45, 50, 55, and 60 weight percent, based upon the total weight of the film.

Suitable fillers are generally stable at temperatures above 450° C., and in some embodiments do not significantly decrease the electrical insulation properties of the film. In some embodiments, the filler is selected from a group consisting of needle-like fillers, fibrous fillers, platelet fillers and mixtures thereof. In one embodiment, the fillers of the present disclosure exhibit an aspect ratio of at least 3, 4, 5, 6, 7, 8, 9, 10, 11, 12, 13, 14, or 15 to 1. In one embodiment, the filler aspect ratio is 6:1 or greater. In another embodiment, the filler aspect ratio is 10:1 or greater, and in another embodiment, the aspect ratio is 12:1 or greater. In some embodiments, the filler is selected from a group consisting of oxides (e.g., oxides comprising silicon, titanium, magnesium and/or aluminum), nitrides (e.g., nitrides comprising boron and/or silicon) or carbides (e.g., carbides comprising tungsten and/or silicon). In some embodiments, the filler comprises oxygen and at least one member of the group consisting of aluminum, silicon, titanium, magnesium and combinations thereof. In some embodiments, the filler comprises platelet talc, acicular titanium dioxide, and/or acicular titanium dioxide, at least a portion of which is coated with an aluminum oxide. In some embodiments, the filler is less than 50, 25, 20, 15, 12, 10, 8, 6, 5, 4, or 2 microns in all dimensions.

In yet another embodiment, carbon fiber and graphite can be used in combination with other fillers to increase mechanical properties. However, oftentimes care must be taken to keep the loading of graphite and/or carbon fiber below 10%, since graphite and carbon fiber fillers can diminish insulation properties and in many embodiments, diminished electrical insulation properties is not desirable. In some embodiments, the filler is coated with a coupling agent. In some embodiments, the filler is coated with an aminosilane coupling agent. In some embodiments, the filler is coated with a dispersant. In some embodiments, the filler is coated with a combination of a coupling agent and a dispersant. Alternatively, the coupling agent and/or dispersant can be incorporated directly into the film and not necessarily coated onto the filler.

In some embodiments, a filtering system is used to ensure that the final film will not contain discontinuous domains greater than the desired maximum filler size. In some embodiments, the filler is subjected to intense dispersion energy, such as agitation and/or high shear mixing or media milling or other dispersion techniques, including the use of dispersing agents, when incorporated into the film (or incorporated into a film precursor) to inhibit unwanted agglomeration above the desired maximum filler size. As the aspect ratio of the filler increases, so too does the tendency of the filler to align or otherwise position itself between the outer surfaces of the film, thereby resulting in a increasingly smooth film, particularly as the filler size decreases.

Generally speaking, surface roughness can increase the probability of electrical or mechanical defects and can diminish property uniformity along the film. In one embodiment, the filler (and any other discontinuous domains) are sufficiently dispersed during film formation, such that the filler (and any other discontinuous domains) are sufficiently between the surfaces of the film upon film formation to provide a final film having an average surface roughness (Ra) of less than 1000, 750, 500 or 400 nanometers. Surface roughness as provided herein can be determined by optical surface profilometry to provide Ra values, such as, by measuring on a Veeco Wyco NT 1000 Series instrument in VSI mode at 25.4× or 51.2× utilizing Wyco Vision 32 software.

In some embodiments, the filler is chosen so that it does not itself degrade or produce off-gasses at the desired processing temperatures. Likewise in some embodiments, the filler is chosen so that it does not contribute to degradation of the polymer.

Useful polyimides of the present disclosure are derived from: i. at least one aromatic diamine, at least 85, 90, 95, 96, 97, 98, 99, 99.5 or 100 mole percent being a rigid rod type monomer; and ii. at least one aromatic dianhydride, at least 85, 90, 95, 96, 97, 98, 99, 99.5 or 100 mole percent being a rigid rod type monomer. Suitable rigid rod type, aromatic diamine monomers include: 1,4-diaminobenzene (PPD), 1,3-diaminobenzene (MPD), 4,4′-diaminobiphenyl, 2,2′-bis(trifluoromethyl) benzidene (TFMB), 1,4-naphthalenediamine, and/or 1,5-naphthalenediamine. Suitable rigid rod type, aromatic dianhydride monomers include pyromellitic dianhydride (PMDA), and/or 3,3′,4,4′-biphenyl tetracarboxylic dianhydride (BPDA).

In some embodiments, other monomers may also be considered for up to 15 mole percent of the aromatic dianhydride and/or up to 15 mole percent of the aromatic diamine, depending upon desired properties for any particular application of the present invention, for example: 3,4′-diaminodiphenyl ether (3,4′-ODA), 4,4′-diaminodiphenyl ether (4,4′-ODA), 4,4′-diaminodiphenyl sulfide, 9,9′-bis(4-aminophenyl)fluorene, 3,3′,4,4′-benzophenone tetracarboxylic dianhydride (BTDA), 4,4′-oxydiphthalic anhydride (ODPA), 3,3′,4,4′-diphenyl sulfone tetracarboxylic dianhydride (DSDA), 2,2-bis(3,4-dicarboxyphenyl) hexafluoropropane dianhydride (6FDA), and mixtures thereof. Polyimides of the present disclosure can be made by methods well known in the art and their preparation need not be discussed in detail here.

In some embodiments, the film is manufactured by incorporating the filler into a film precursor material, such as, a solvent, monomer, prepolymer and/or polyamic acid composition. Ultimately, a filled polyamic acid composition is generally cast into a film, which is subjected to drying and curing (chemical and/or thermal curing) to form a filled polyimide free-standing or non free-standing film. Any conventional or non-conventional method of manufacturing filled polyimide films can be used in accordance with the present disclosure. The manufacture of filled polyimide films is well known and need not be further described here. In one embodiment, the polyimide of the present disclosure has a high glass transition temperature (Tg) of greater than 300, 310, 320, 330, 340, 350, 360, 370 380, 390 or 400° C. A high Tg generally helps maintain mechanical properties, such as storage modulus, at high temperatures.

In some embodiments, the crystallinity and amount of crosslinking of the polyimide interposer film can aid in storage modulus retention. In one embodiment, the polyimide interposer film storage modulus (as measured by dynamic mechanical analysis, DMA) at 480° C. is at least: 400, 450, 500, 550, 600, 650, 700, 750, 800, 850, 900, 950, 1000, 1100, 1200, 1300, 1400, 1500, 1600, 1800, 2000, 2200, 2400, 2600, 2800, 3000, 3500, 4000, 4500, or 5000 MPa.

In some embodiments, the polyimide interposer film of the present disclosure has an isothermal weight loss of less than 1, 0.75, 0.5 or 0.3 percent at 500° C. over about 30 minutes. Polyimides of the present disclosure have high dielectric strength, generally higher than common inorganic insulators. In some embodiments, polyimides of the present disclosure have a breakdown voltage equal to or greater than 10 V/micrometer. In some embodiments the filler is selected from a group consisting of oxides, nitrides, carbides and mixtures thereof, and the film has at least 1, 2, 3, 4, 5, or all 6 of the following properties: i. a Tg greater than 300° C., ii. a dielectric strength greater 500 volts per 25.4 microns, iii. an isothermal weight loss of less than 1% at 500° C. over 30 minutes, iv. an in-plane CTE of less than 25 ppm/° C., v. an absolute value stress free slope of less than 10 times (10)⁻⁶ per minute, and vi. an eₘₐₓ of less than 1% at 7.4-8MPa. In some embodiments, the film of the present disclosure is reinforced with a thermally stable, inorganic: fabric, paper, sheet, scrim or a combination thereof.

In some embodiments, electrically insulating fillers may be added to modify the electrical properties of the film. In some embodiments, it is important that the polyimide interposer film be free of pinholes or other defects (foreign particles, gels, filler agglomerates or other contaminates) that could adversely impact the electrical integrity and dielectric strength of the polyimide interposer film, and this can generally be addressed by filtering. Such filtering can be done at any stage of the film manufacture, such as, filtering solvated filler before or after it is added to one or more monomers and/or filtering the polyamic acid, particularly when the polyamic acid is at low viscosity, or otherwise, filtering at any step in the manufacturing process that allows for filtering. In one embodiment, such filtering is conducted at the minimum suitable filter pore size or at a level just above the largest dimension of the selected filler material.

A single layer film can be made thicker in an attempt to decrease the effect of defects caused by unwanted (or undesirably large) discontinuous phase material within the film. Alternatively, multiple layers of polyimide may be used to diminish the harm of any particular defect (unwanted discontinuous phase material of a size capable of harming desired properties) in any particular layer, and generally speaking, such multilayers will have fewer defects in performance compared to a single polyimide layer of the same thickness. Using multiple layers of polyimide films can diminish or eliminate the occurrence of defects that may span the total thickness of the film, because the likelihood of having defects that overlap in each of the individual layers tends to be extremely small. Therefore, a defect in any one of the layers is much less likely to cause an electrical or other type failure through the entire thickness of the film. In some embodiments, the polyimide interposer film comprises two or more polyimide layers. In some embodiments, the polyimide layers are the same. In some embodiments, the polyimide layers are different. In some embodiments, the polyimide layers independently may comprise a thermally stable filler, reinforcing fabric, inorganic paper, sheet, scrim or combinations thereof. Optionally, 0-55 weight percent of the film also includes other ingredients to modify properties as desired or required for any particular application.

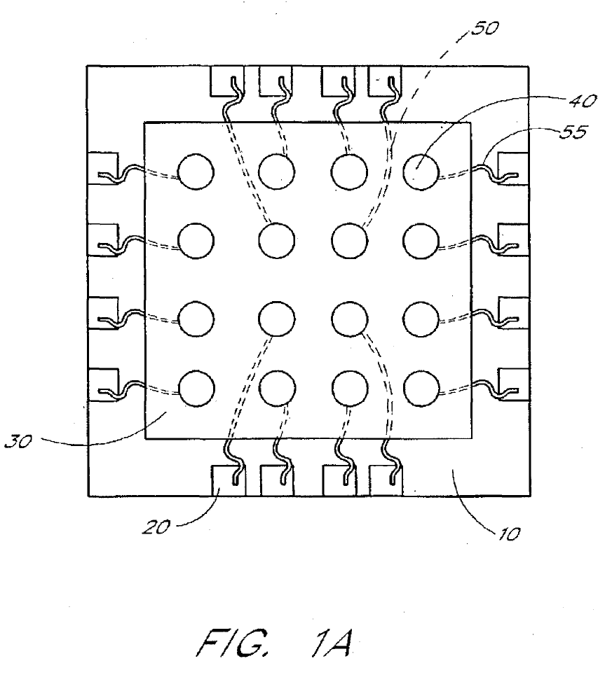

FIGS. 1A and 1B show a face view and a fragmentary cross-sectional view, respectively, of a chip 10 having a plurality of chip contacts 20 on a contact bearing surface. An interposer layer 30 overlies and is typically centrally located on the contact bearing surface of the chip 10 so that the chip contacts 20 are exposed. The interposer layer 30 may merely overlie the contact bearing surface of the chip 10; however, typically, the interposer layer is adhesively attached to the chip surface using a thin layer of adhesive material 80, as shown in FIG. 1B.

The interposer layer 30 may comprise a rigid or flexible material. Preferably, the interposer layer comprises a sheet of polyimide having a thickness approximately between 2 and 100 microns. The first surface of the interposer layer 30 has a plurality of conductive terminals 40 thereon.

The terminals 40 are electrically connected to a chip contact 20 through respective conductive leads 50 extending along the opposite side of the substrate and connected to the leads 50 through conductive vias 70. Alternately, the substrate may simply be removed so that solder ball terminals are placed directly onto the ends of the leads 50 without requiring the conductive vias 70.

Each lead 50 has an expansion section 55 extending from an edge of the interposer layer 30. Each expansion section is bonded to a respective chip contact 20, typically using conventional ultrasonic or thermosonic bonding apparatus. Each expansion section 55 is laterally curved substantially parallel to the plane of the interposer layer 30 prior to the bonding operation. Preferably, each expansion section 55 laterally curves at least twice in opposite directions (substantially “s” shaped) and may be curved more than twice. The leads 50 may further be detachably connected to a supporting structure prior to bonding as disclosed in U.S. Pat. Nos. 5,489,749 and 5,536,909.

Typically, the expansion sections 55 of the leads are encapsulated by a suitable encapsulant, such as silicone or epoxy, to protect them from contamination and damage. During operation of the packaged chip, the terminals are attached to a printed circuit board and the laterally curved shape of the expansion sections 55 of the leads 50 helps to compensate for the expansion and contraction of the chip during thermal cycling by having the ability to independently flex and bend. The aforementioned encapsulant 60 supports the expansion sections 55 of the leads 50 as they flex and bend and further helps to spread the forces acting on the leads. Further, a solder mask or coverlay may be placed over the exposed surface of the substrate 30 after the bonding and encapsulation steps such that only the terminals are exposed.

FIG. 1C shows a fragmentary cross-sectional view of an alternate embodiment in which the leads 50′ are located on the same side as the terminals 40; thus, not requiring the conductive vias 70 (shown in FIG. 1B). A solder mask/coverlay is also used in the embodiment shown in FIG. 1C because the leads 50 and the terminals 40 are on the same side of the interposer layer 30. The solder mask/coverlay provides a dielectric coating ensuring that the solder connecting the terminals to contacts on the printed circuit board does not wick down the leads or short to other soldered terminals.

FIG. 1D shows a fragmentary cross-sectional view of an alternate embodiment in which the thin layer of adhesive from FIG. 1B has been replaced with a thicker layer of compliant material 80′ to give added compensation for thermal mismatch, as disclosed in U.S. Pat. Nos. 5,148,265 and 5,148,266. The compliant material 80′ is typically about 50 to 200 microns thick and comprises either a thermoset or a thermoplastic material. The structure shown in FIG. 1D also allows the expansion sections 55 of the leads 50 to be shaped by the bonding operation so that they are curved in a direction perpendicular to the lateral curve of the leads 50. As stated above, these laterally and vertically curved leads are typically supported by the encapsulant 60 so as to spread the forces acting upon them during thermal cycling of the operational package. Further details regarding these and other embodiments are disclosed in U.S. Pat. No. 5,821,608.

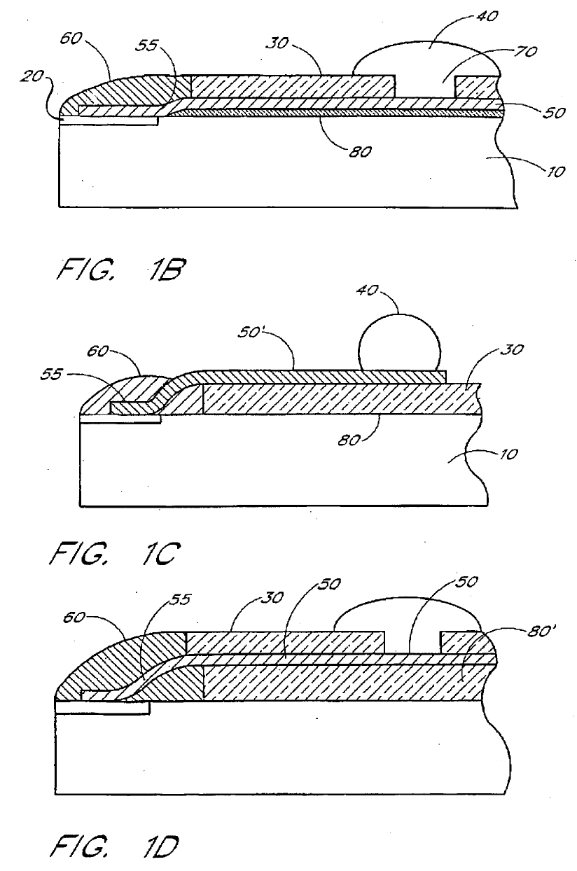

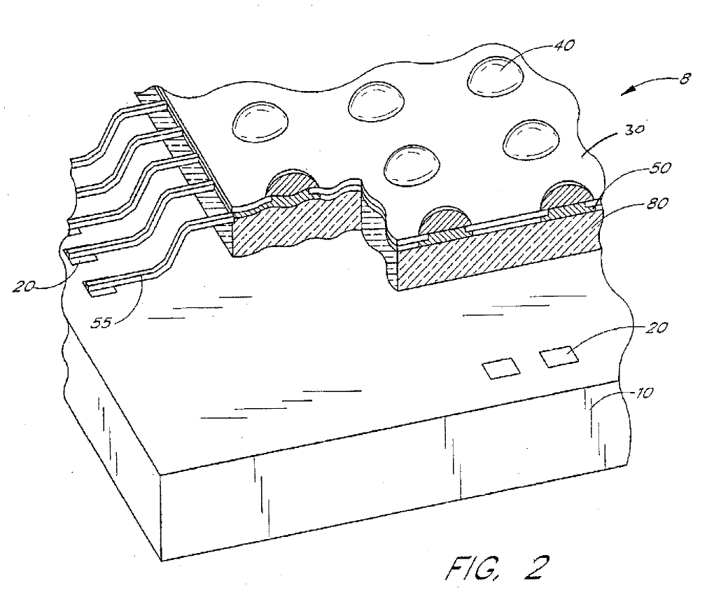

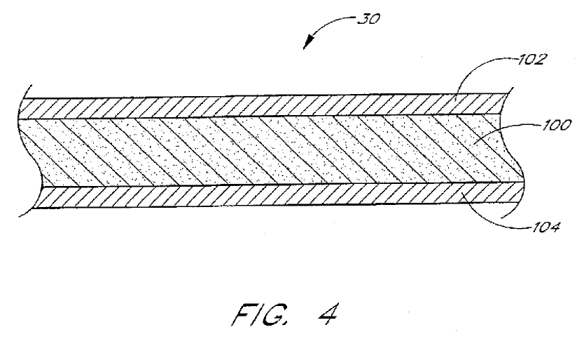

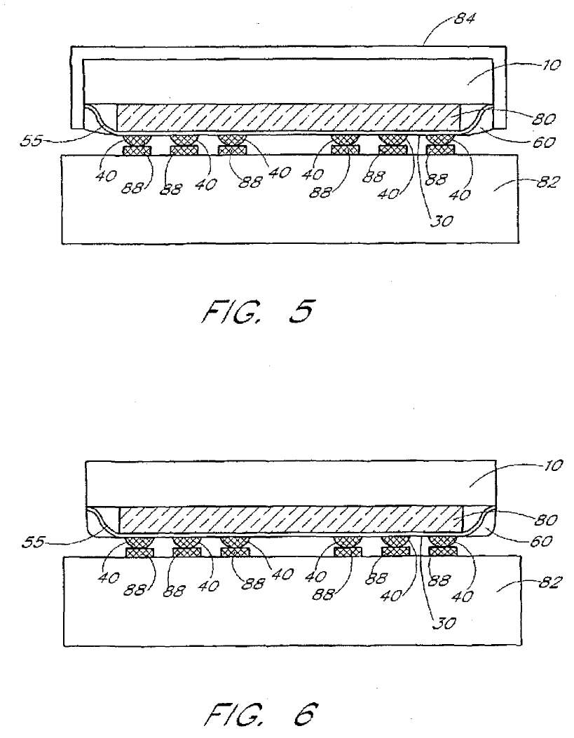

FIGS. 2 and 3 illustrate one embodiment of the present invention in which a first level package 8 is provided, wherein like components are numbered in accordance with FIGS. 1A-1D above. In the IC packaging industry, it is common to refer to the placement of the IC chip within a suitable package as “1st level” packaging. The placement or mounting of the IC package on a suitable printed circuit board (PCB) or other substrate, is referred to as “2nd level” packaging. The interconnection of the various PCBs or other carriers within an electronic system, e.g., through use of a motherboard, is referred to as “3rd level” packaging. In one embodiment, the package 8 is a ball grid array (BGA) package having a plurality of solder balls 40 that interconnect the package to a printed circuit board (see FIGS. 5 and 6). As shown in FIGS. 2 and 3, in this package 8, a die or chip 10 is prepared for bonding with a second level package. As shown in FIG. 5, the integrated circuit die 10 of the BGA package is mounted to a printed circuit board 82 through solder pads 88 and enclosed by a rigid housing or lid 84, typically constructed from a molded plastic material. FIG. 6 illustrates an alternative embodiment of the pBGA package without a package case 84.

The die 10 will be understood by one of ordinary skill in the art to be one of many different types of integrated circuit. For example, the die 10 can be from a wide range of integrated circuit products, such as microprocessors, co-processors, digital signal processors, graphics processors, microcontrollers, memory devices, reprogrammable devices, programmable logic devices, and logic arrays, etc.

A die attach material 80 is provided over the central portion of the die 10. A solder ball array 40 is provided over the die attach material. The solder ball array 40 serves to make the connection to the next-level package. The die attach material 80 may be a silicone clastomer, or an epoxy-modified elastomeric material. The solder balls 40 are preferably relatively flexible and can thus compensate for any lack of flatness in the printed circuit board or package. Additionally, the solder balls are assembled in an array, and thus provide a relatively high throughput. In one preferred embodiment, the solder balls are made of a tin/lead (SnPb) eutectic material such as Sn63Pb37 and have a diameter of about 0.3 to 0.5 mm.

The interposer film 30 extends over the die attach material 80 to form a connection with the solder ball array 40. The bump pitch of the solder balls 40 on the interposer film 30 can be as small as about 0.25 to 1 mm, and is more preferably about 0.5 mm. Leads 50 extend from the interposer film 30 to form a connection with the die 10 at die pads 20. The leads are preferably made of Au wire, and are preferably bonded thermosonically in a lazy-S shape in expansion section 55 to accommodate deformation due to thermal expansion.

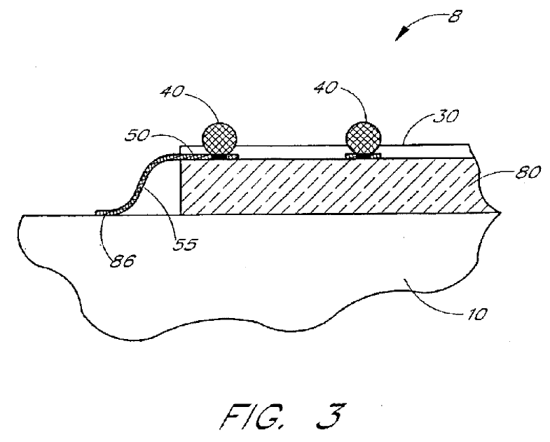

FIG. 4 illustrates more particularly in cross-section the interposer film 30. The interposer film 30 includes a composite polyimide core 100 and conductive traces 102 and 104, which are preferably made of copper. The polyimide core 100 preferably has a thickness of about 25 μm. The copper traces preferably have a thickness of about 12 μm.

The increased rigidity of the interposer film 100 advantageously makes the interposer film easier to handle during fabrication of the package. With conventional interposer films, having a modulus in the range of about 4.5 to 8 GPa for example, during assembly of the package the interposer is carried using a metal frame as described above. The composite interposer of the preferred embodiments, by contrast, has a higher modulus which may eliminate the need to use a metal frame. For example, filler may be added so that the modulus of the interposer is about 5 and 500% higher than the modulus of the polyimide core alone. This thereby simplifies manufacture, and the increased rigidity of the interposer film makes it possible to handle the interposer film directly by a machine without using a metal frame. Elimination of the metal frame helps the process accuracy and reduces handling and costs.

Moreover, the more rigid interposer of the preferred embodiments also prevents die delamination. This is because a more rigid interposer can be made flatter and can therefore be adhered to the die attach material more effectively.

It will be appreciated that the interposer layer described herein may be used not only in μBGA packages, but also in other integrated circuit packages as well. Other types of integrated circuit package applications as would be known by one of skill in the art include, but are not limited to, any package using a flexible substrate.

The embodiments illustrated and described above are provided merely as examples of certain preferred embodiments of the present invention. Various changes and modifications can be made from the embodiments presented herein by those skilled in the art without departure from the spirit and scope of the invention, as defined by the appended claims.

### EXAMPLES

The invention will be further described in the following examples, which are not intended to limit the scope of the invention described in the claims. In these examples, “prepolymer” refers to a lower molecular weight polymer made with a slight stoichiometric excess of diamine monomer (ca. 2%) to yield a Brookfield solution viscosity in the range of about 50-100 poise at 25° C. Increasing the molecular weight (and solution viscosity) was accomplished by adding small incremental amounts of additional dianhydride in order to approach stoichiometric equivalent of dianhydride to diamine.

### Example 1

BPDA/PPD prepolymer (69.3 g of a 17.5 wt % solution in anhydrous DMAC) was combined with 5.62 g of acicular TiO₂ (FTL-110, Ishihara Corporation, USA) and the resulting slurry was stirred for 24 hours. In a separate container, a 6 wt % solution of pyromellitic anhydride (PMDA) was prepared by combining 0.9 g of PMDA (Aldrich 412287, Allentown, Pa.) and 15 ml of DMAC.

The PMDA solution was slowly added to the prepolymer slurry to achieve a final viscosity of 653 poise. The formulation was stored overnight at 0° C. to allow it to degas.

The formulation was cast using a 25 mil doctor blade onto a surface of a glass plate to form a 3″×4″ film. The glass was pretreated with a release agent to facilitate removal of the film from the glass surface. The film was allowed to dry on a hot plate at 80° C. for 20 minutes. The film was subsequently lifted off the surface, and mounted on a 3″×4″ pin frame.

After further drying at room temperature under vacuum for 12 hours, the mounted film was placed in a furnace (Thermolyne, F6000 box furnace). The furnace was purged with nitrogen and heated according to the following temperature protocol:
125° C. (30 min)
125° C. to 350° C. (ramp at 4° C./min)
350° C. (30 min)
350° C. to 450° C. (ramp at 5° C./min)
450° C. (20 min)
450° C. to 40° C. (cooling at 8° C./min)

### Comparative Example A

An identical procedure as described in Example 1 was used, except that no TiO₂ filler was added to the prepolymer solution. The final viscosity, before casting, was 993 poise.

### Example 2

The same procedure as described in Example 1 was used, except that 69.4 g of BPDA/PPD prepolymer (17.5 wt % in DMAC) was combined with 5.85 g of TiO₂ (FTL-200, Ishihara USA). The final viscosity of the formulation prior to casting was 524 poise.

### Example 3

The same procedure as described in Example 1 was used, except that 69.4 g of BPDA/PPD prepolymer was combined with 5.85 g of acicular TiO₂ (FTL-300, Ishihara USA). The final viscosity prior to casting was 394 poise.

### Example 4A

The same procedure as described in Example 1 was used, except that 69.3 g of BPDA/PPD prepolymer (17.5 wt % in DMAC) was combined with 5.62 g of acicular TiO₂ (FTL-100, Ishihara USA).

The material was filtered through 80 micron filter media (Millipore, polypropylene screen, 80 micron, PP 8004700) before the addition of the PMDA solution in DMAC.

The final viscosity before casting was 599 poise.

### Example 4

The same procedure as described in Example 1 was followed, except that 139 g of BPDA/PPD prepolymer (17.5 wt % in DMAC) was combined with 11.3 g of acicular TiO₂ (FTL-100). The mixture of BPDA/PPD prepolymer with acicular TiO₂ (FTL-110) was placed in a small container. A Silverson Model L4RT high-shear mixer (Silverson Machines, LTD, Chesham Baucks, England) equipped with a square-hole, high-shear screen was used to mix the formulation (with a blade speed of approximately 4000 rpm) for 20 minutes. An ice bath was used to keep the formulation cool during the mixing operation.

The final viscosity of the material before casting was 310 poise.

### Example 5

The same procedure as described in Example 4 was used, except that 133.03 g of BPDA/PPD prepolymer (17.5 wt % in DMAC) was combined with 6.96 g of acicular TiO₂ (FTL-110).

The material was placed a small container and mixed with a high-shear mixer (with a blade speed of approximately 4000 rpm) for approximately 10 min. The material was then filtered through 45 micron filter media (Millipore, 45 micron polypropylene screen, PP4504700).

The final viscosity was approximately 1000 poise, prior to casting.

### Example 6

The same procedure as described in Example 5 was used, except that 159.28 g of BPDA/PPD prepolymer was combined with 10.72 g of acicular TiO₂ (FTL-110). The material was mixed with a high-shear mixer for 5-10 minutes.

The final formulation viscosity prior to casting was approximately 1000 poise.

### Example 7

The same procedure as described in Example 5 was used, except that 157.3 g of BPDA/PPD prepolymer was combined with 12.72 grams of acicular TiO₂ (FTL-110). The material was blended with the high shear mixer for approximately 10 min.

The final viscosity prior to casting was approximately 1000 poise.

### Example 8

A procedure similar to that described in Example 5 was used, except that 140.5 g of DMAC was combined with 24.92 g of TiO₂ (FTL-110). This slurry was blended using a high-shear mixer for approximately 10 minutes.

This slurry (57.8 g) was combined with 107.8 g of BPDA/PPD prepolymer (17.5 wt % in DMAC) in a 250 ml, 3-neck, round-bottom flask. The mixture was slowly agitated with a paddle stirrer overnight under a slow nitrogen purge. The material was blended with the high-shear mixer a second time (approximately 10 min, 4000 rpm) and then filtered through 45 micron filter media (Millipore, 45 micron polypropylene, PP4504700).

The final viscosity was 400 poise.

### Example 9

The same procedure as described in Example 8 was used, except that 140.49 g of DMAC was combined with 24.89 g of talc (Flex Talc 610, Kish Company, Mentor, Ohio). The material was blended using the high-shear mixing procedure described in Example 8.

This slurry (69.34 g) was combined with 129.25 g of BPDA/PPD prepolymer (17.5 wt % in DMAC), mixed using a high-shear mixer a second time, and then filtered through 25 micron filter media (Millipore, polypropylene, PP2504700) and cast at 1600 poise.

### Example 10

This formulation was prepared at a similar volume % (with TiO₂, FTL-110) to compare with Example 9. The same procedure as described in Example 1 was used. 67.01 g of BPDA/PPD prepolymer (17.5 wt %) was combined with 79.05 grams of acicular TiO₂ (FTL-110) powder.

The formulation was finished to a viscosity of 255 poise before casting.

A Dynamic Mechanical Analysis (DMA) instrument was used to characterize the mechanical behavior of Comparative Example A and Example 10. DMA operation was based on the viscoelastic response of polymers subjected to a small oscillatory strain (e.g., 10 μm) as a function of temperature and time (TA Instruments, New Castle, Del., USA, DMA 2980). The films were operated in tension and multifrequency-strain mode, where a finite size of rectangular specimen was clamped between stationary jaws and movable jaws. Samples of 6-6.4 mm width, 0.03-0.05 mm thickness and 10 mm length in the MD direction were fastened with 3 in-lb torque force. The static force in the length direction was 0.05 N with autotension of 125%. The film was heated at frequency of 1 Hz from 0° C. to 500° C. at 3° C./min rate. The storage modulii at room temperature, 500 and 480° C. are recorded on Table 1.

The coefficient of thermal expansion of Comparative Example A and Example 10 were measured by thermomechanical analysis (TMA). A TA Instrument model 2940 was set up in tension mode and furnished with an N₂ purge of 30-50 ml/min rate and a mechanical cooler. The film was cut to a 2.0 mm width in the MD (casting) direction and clamped lengthwise between the film clamps allowing a 7.5-9.0 mm length. The preload tension was set for 5 grams force. The film was then subjected to heating from 0° C. to 400° C. at 10° C./min rate with 3 minutes hold, cooling back down to 0° C. and reheating to 400° C. at the same speed. The calculations of thermal expansion coefficient in units of μm/m-C (or ppm/° C.) from 60° C. to 400° C. were reported for the casting direction (MD) for the second heating cycle over 60° C. to 400° C., and also over 60° C. to 350° C.

A thermogravimetric analysis instrument (TA, Q5000) was used for sample measurements of weight loss. Measurements were performed in flowing nitrogen. The temperature program involved heating at a rate of 20° C./min to 500° C. The weight loss after holding for 30 minutes at 500° C. is calculated by normalizing to the weight at 200° C., where any adsorbed water was removed, to determine the decomposition of polymer at temperatures above 200° C.

TABLE 1

| | Storage Modulus | CTE, | TGA, % wt loss at |
|---|---|---|---|
| | (DMA) at 500° C. | ppm/° C. | 500° C., 30 min, |
| | (480° C.), | 400 C., | normalized to |
| Example # | MPa | (350° C.) | weight at 200 C. |
| 10 | 4000 (4162) | 17.9, (17.6) | 0.20 |
| Comparative A | Less than 200 | 11.8, (10.8) | 0.16 |
| | (less than 200) | | |

### Comparative Example B

The same procedure as described in Example 8 was used, with the following differences. 145.06 g of BPDA/PPD prepolymer was used (17.5 wt % in DMAC).

127.45 grams of Wallastonite powder (Vansil HR325, R. T. Vanderbilt Company, Norwalk Conn.) having a smallest dimension greater than 800 nanometers (as calculated using an equivalent cylindrical width defined by a 12:1 aspect ratio and an average equivalent spherical size distribution of 2.3 microns) was combined with 127.45 grams of DMAC and high shear mixed according to the procedure of Example 8.

145.06 g of BPDA/PPD prepolymer (17.5 wt % in DMAC) was combined with 38.9 grams of the high shear mixed slurry of wollastonite in DMAC. The formulation was high shear mixed a second time, according to the procedure of Example 8.

The formulation was finished to a viscosity of 3100 poise and then diluted with DMAC to a viscosity of 600 poise before casting.

### Measurement of High Temperature Creep

A DMA (TA Instruments Q800 model) was used for a creep/recovery study of film specimens in tension and customized controlled force mode. A pressed film of 6-6.4 mm width, 0.03-0.05 mm thickness and 10 mm length was clamped between stationary jaws and movable jaws in 3 in-lb torque force. The static force in the length direction was 0.005N. The film was heated to 460° C. at 20° C./min rate and held at 460° C. for 150 min. The creep program was set at 2 MPa for 20 min, followed by recovery for 30 min with no additional force other than the initial static force of (0.005N). The creep/recovery program was repeated for 4 MPa and 8 MPa and the same time intervals as that for 2 MPa.

In Table 2 below are tabulated the strain and the recovery following the cycle at 8 MPa (more precisely, the maximum stress being from about 7.4 to 8.0 MPa). The elongation is converted to a unitless equivalent strain by dividing the elongation by the starting film length. The strain at 8 MPa (more precisely, the maximum stress being from about 7.4 to 8.0 MPa) and 460° C. is tabulated, “emax”. The term “e max” is the dimensionless strain which is corrected for any changes in the film due to decomposition and solvent loss (as extrapolated from the stress free slope) at the end of the 8 MPa cycle (more precisely, the maximum stress being from about 7.4 to 8.0 MPa). The term “e rec” is the strain recovery immediately following the 8 MPa cycle (more precisely, the maximum stress being from about 7.4 to 8.0 MPa), but at no additional applied force (other than the initial static force of 0.005 N), which is a measure of the recovery of the material, corrected for any changes in film due to decomposition and solvent loss as measured by the stress free slope). The parameter, labeled “stress free slope”, is also tabulated in units of dimensionless strain/min and is the change in strain when the initial static force of 0.005 N is applied to the sample after the initial application of the 8 Mpa stress (more precisely, the maximum stress being from about 7.4 to 8.0 MPa). This slope is calculated based on the dimensional change in the film (“stress free strain”) over the course of 30 min following the application of the 8 MPa stress cycle (more precisely, the maximum stress being from about 7.4 to 8.0 MPa). Typically the stress free slope is negative. However, the stress free slope value is provided as an absolute value and hence is always a positive number.

The third column, e plast, describes the plastic flow, and is a direct measure of high temperature creep, and is the difference between e max and e rec.

In general, a material which exhibits the lowest possible strain (e max), the lowest amount of stress plastic flow (e plast) and a low value of the stress free slope is desirable.

TABLE 2

| | | | | | | Absolute | Wt | |
|---|---|---|---|---|---|---|---|---|
| | | | | | Plastic | Value | fraction | |
| | | | e max | | deformation | Stress | of | Vol fraction |
| | | Applied | (strain at | | ((eplast) = e | Free | inorganic | inorganic |
| | | Stress | applied | | max − e | Slope | filler in | filler in |
| Example | Additive | (MPA)* | stress) | e rec | rec)) | (/min) | polyimide | polyimide* |
| Example 1 | TiO₂ | 7.44 | 4.26E−03 | 3.87E−03 | 3.89E−04 | 2.82E−06 | 0.338 | 0.147 |
| | (FLT-110) | | | | | | | |
| Comparative | None | 7.52 | 1.50E−02 | 1.40E−02 | 9.52E−04 | 9.98E−06 | | |
| Example A | | | | | | | | |
| Example 2* | TiO₂ | 4.64 | 3.45E−03 | 3.09E−03 | 3.67E−04 | 2.88E−06 | 0.346 | 0.152 |
| | (FLT-200) | | | | | | | |
| Example 3 | TiO₂ | 7.48 | 2.49E−03 | 2.23E−03 | 2.65E−04 | 1.82E−06 | 0.346 | 0.152 |
| | (FLT-300) | | | | | (82% | | |
| | | | | | | lower | | |
| | | | | | | than | | |
| | | | | | | comparative | | |
| | | | | | | example) | | |
| Example 4 A | TiO₂ | 7.48 | 3.56E−03 | 3.18E−03 | 3.77E−04 | 3.40E−06 | 0.338 | 0.147 |
| | (FLT-100) | | | | | | | |
| Example 4 | TiO₂ | 7.45 | 2.42E−03 | 2.20E−03 | 2.16E−04 | 1.73E−06 | 0.338 | 0.147 |
| | (FLT-110) | | | | | | | |
| Example 5 | TiO₂ | 7.48 | 7.83E−03 | 7.05E−03 | 7.84E−04 | 5.61E−06 | 0.247 | 0.100 |
| | (FLT-110) | | | | | | | |
| Example 6 | TiO₂ | 7.46 | 4.35E−03 | 3.97E−03 | 3.82E−04 | 2.75E−06 | 0.297 | 0.125 |
| | (FLT-110) | | | | | | | |
| Example 7 | TiO₂ | 7.46 | 3.32E−03 | 3.02E−03 | 3.00E−04 | 1.98E−06 | 0.337 | 0.147 |
| | (FLT-110) | | | | | | | |
| Example 8 | TiO₂ | 8.03 | 3.83E−03 | 3.53E−03 | 2.97E−04 | 3.32E−06 | 0.337 | 0.146 |
| | (FLT-110) | | | | | | | |
| Example 9 | Talc | 8.02 | 5.65E−03 | 4.92E−03 | 7.23E−04 | 7.13E−06 | 0.337 | 0.208 |
| Example 10 | TiO₂ | 7.41 | 1.97E−03 | 1.42E−04 | 2.66E−04 | 1.37E−06 | 0.426 | 0.200 |
| | (FTL-110) | | | | | | | |
| Comparative B | Wollastonite | 8.02 | 1.07E−02 | 9.52E−03 | 1.22E−03 | 1.15E−05 | 0.255 | 0.146 |
| | powder | | | | | | | |

*Maximum applied stress was in a range from 7.4 to 8.0 MPa, except for Example 2 which was conducted at 4.64 MPa

Table 2 provides filler loadings in both weight fraction and volume fraction. Filler loadings of similar volume fractions are generally a more accurate comparison of fillers, since filler performance tends to be primarily a function of space occupied by the filler, at least with respect to the present disclosure. The volume fraction of the filler in the films was calculated from the corresponding weight fractions, assuming a fully dense film and using these densities for the various components:
1.42 g/cc for density of polyimide; 4.2 g/cc for density of acicular TiO₂;
2.75 g/cc for density of talc; and 2.84 g/cc for wollastonite

### Example 11

168.09 grams of a polyamic acid (PAA) prepolymer solution prepared from BPDA and PPD in DMAC (dimethylacetamide) with a slight excess of PPD (15 wt % PAA in DMAC)) were blended with 10.05 grams of Flextalc 610 talc for 2 minutes in a Thinky ARE-250 centrifugal mixer to yield an off-white dispersion of the filler in the PAA solution.

The dispersion was then pressure-filtered through a 45 micron polypropylene filter membrane. Subsequently, small amounts of PMDA (6 wt % in DMAC) were added to the dispersion with subsequent mixing to increase the molecular weight and thereby the solution viscosity to about 3460 poise. The filtered solution was degassed under vacuum to remove air bubbles and then this solution was coated onto a piece of Duofoil® aluminum release sheet (˜9 mil thick), placed on a hot plate, and dried at about 80-100° C. for 30 min to 1 hour to a tack-free film.

The film was subsequently carefully removed from the substrate and placed on a pin frame and then placed into a nitrogen purged oven, ramped from 40° C. to 320° C. over about 70 minutes, held at 320° C. for 30 minutes, then ramped to 450° C. over 16 minutes and held at 450° C. for 4 minutes, followed by cooling. The film on the pin frame was removed from the oven and separated from the pin frame to yield a filled polyimide film (about 30 wt % filler).

The approximately 1.9 mil (approximately 48 micron) film exhibited the following properties.
Storage modulus (E′) by Dynamic Mechanical Analysis (TA Instruments, DMA-2980, 5° C./min) of 12.8 GPa at 50° C. and 1.3 GPa at 480° C., and a Tg (max of tan delta peak) of 341° C.
Coefficient of thermal expansion (TA Instruments, TMA-2940, 10° C./min, up to 380° C., then cool and rescan to 380° C.) of 13 ppm/° C. and 16 ppm/° C. in the cast and transverse directions, respectively, when evaluated between 50-350° C. on the second scan.
Isothermal weight loss (TA Instruments, TGA 2050, 20° C./min up to 500° C. then held for 30 min at 500° C.) of 0.42% from beginning to end of isothermal hold at 500° C.

### Comparative Example C

200 grams of a polyamic acid (PAA) prepolymer solution prepared from BPDA and PPD in DMAC with a slight excess of PPD (15 wt % PAA in DMAC,) were weighed out. Subsequently, small amounts of PMDA (6 wt % in DMAC) were added stepwise in a Thinky ARE-250 centrifugal mixer to increase the molecular weight and thereby the solution viscosity to about 1650 poise. The solution was then degassed under vacuum to remove air bubbles and then this solution was coated onto a piece of Duofoil® aluminum release sheet (-9 mil thick), placed on a hot plate and dried at about 80-100° C. for 30 min to 1 hour to a tack-free film. The film was subsequently carefully removed from the substrate and placed on a pin frame then placed into a nitrogen purged oven, ramped from 40° C. to 320° C. over about 70 minutes, held at 320° C. for 30 minutes, then ramped to 450° C. over 16 minutes and held at 450° C. for 4 minutes, followed by cooling. The film on the pin frame was removed from the oven and separated from the pin frame to yield a filled polyimide film (0 wt % filler).

The approximately 2.4 mil (approximately 60 micron) film exhibited the following properties.
Storage modulus (E′) by Dynamic Mechanical Analysis (TA Instruments, DMA-2980, 5° C./min) of 8.9 GPa at 50° C., and 0.3 GPa at 480° C., and a Tg (max of tan delta peak) of 348° C.
Coefficient of thermal expansion (TA Instruments, TMA-2940, 10° C./min, up to 380° C., then cool and rescan to 380° C.) of 18 ppm/° C. and 16 ppm/° C. in the cast and transverse directions, respectively, when evaluated between 50-350° C. on the second scan.
Isothermal weight loss (TA Instruments, TGA 2050, 20° C./min up to 500° C. then held for 30 min at 500° C.) of 0.44% from beginning to end of isothermal hold at 500° C.

### Example 12

In a similar manner to Example 11, a polyamic acid polymer with Flextalc 610 at about 30 wt % was cast onto a 5 mil polyester film. The cast film on the polyester was placed in a bath containing approximately equal amounts of acetic anhydride and 3-picoline at room temperature. As the cast film imidized in the bath, it began to release from the polyester. At this point, the cast film was removed from the bath and the polyester, placed on a pinframe, and then placed in a oven and ramped as described in Example 11. The resulting talc-filled polymide film exhibited a CTE by TMA (as in Example 11) of 9 ppm/° C. and 6 ppm/° C. in the cast and transverse directions, respectively.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and any figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

When an amount, concentration, or other value or parameter is given as either a range, preferred range or a list of upper values and lower values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

What is claimed is:

1. A process for forming an interposer film for an integrated circuit package, comprising:
depositing onto a substrate a plurality of electrically conductive domains, wherein the substrate comprises:
a) a polyimide in an amount from 40 to 95 weight percent of the substrate, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
a) is less than 800 nanometers in at least one dimension;
b) has an aspect ratio greater than 3:1;
c) is less than the thickness of the film in all dimensions; and
d) is present in an amount from 5 to 60 weight percent of
the total weight of the film,
the substrate having a thickness from 4 to 150 microns.

2. A process according to claim 1 wherein deposition of the electrically conductive domains is effected on a continuous web of the substrate.

3. A process according to claim 2 wherein the continuous web of substrate is a component of a reel to reel process.

4. A process according to claim 1 wherein the filler is smaller than 600 nm in at least one dimension.

5. A process according to claim 1 wherein the filler comprises acicular titanium dioxide.

6. A process according to claim 1 wherein the filler comprises an acicular titanium dioxide, at least a portion of which is coated with an aluminum oxide.

7. A process according to claim 1 wherein:
a) the rigid rod type dianhydride is selected from a group consisting of 3,3′,4,4′-biphenyl tetracarboxylic dianhydride (BPDA), pyromellitic dianhydride (PMDA), and mixtures thereof; and
b) the rigid rod type diamine is selected from 1,4-diaminobenzene (PPD), 4,4′-diaminobiphenyl, 2,2′-bis(trifluoromethyl) benzidene (TFMB), 1,5-naphthalenediamine, 1,4-naphthalenediamine, and mixtures thereof.

8. A process according to claim 1 wherein at least 25 mole percent of the diamine is 1,5-naphthalenediamine.

9. A process according to claim 1 wherein the substrate comprises a coupling agent, a dispersant or a combination thereof.

10. A process according to claim 1 wherein the filler is selected from a group consisting of oxides, nitrides, carbides and mixtures thereof, and the substrate has the following properties: (i) a Tg greater than 300° C., (ii) a dielectric strength greater than 500 volts per 25.4 microns, (iii) an isothermal weight loss of less than 1% at 500° C. over 30 minutes, (iv) an in-plane CTE of less than 25 ppm/° C., (v) an absolute value stress free slope of less than 10 times (10)⁻⁶ per minute, and (vi) an eₘₐₓ of less than 1% at 7.4-8 MPa.

11. A process according to claim 1 wherein the substrate comprises two or more layers.

12. A process according to claim 1 wherein the substrate is reinforced with a thermally stable, inorganic: fabric, paper, sheet, scrim or a combination thereof.

13. An interposer film for IC packaging comprising a plurality of electrically conductive domains supported by a substrate, wherein the substrate comprises:
a) a polyimide in an amount from 40 to 95 weight percent of the substrate, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
a) is less than 800 nanometers in at least one dimension;
b) has an aspect ratio greater than 3:1;
c) is less than the thickness of the film in all dimensions; and
d) is present in an amount from 5 to 60 weight percent of the total weight of the film,
the substrate having a thickness from 8 to 150 microns.

14. An interposer film in accordance with claim 13, wherein:
a) the rigid rod type dianhydride is selected from a group consisting of 3,3′,4,4′-biphenyl tetracarboxylic dianhydride (BPDA), pyromellitic dianhydride (PMDA), and mixtures thereof; and
b) the rigid rod type diamine is selected from 1,4-diaminobenzene (PPD), 4,4′-diaminobiphenyl, 2,2′-bis(trifluoromethyl) benzidene (TFMB), 1,5-naphthalenediamine, 1,4-naphthalenediamine, and mixtures thereof.

15. An interposer film according to claim 13 wherein the filler is smaller than 600 nm in at least one dimension.

16. An interposer film according to claim 13 wherein the filler comprises acicular titanium dioxide.

17. An interposer film according to claim 13 wherein the filler comprises an acicular titanium dioxide, at least a portion of which is coated with an aluminum oxide.

18. An interposer film according to claim 13 wherein at least 25 mole percent of the diamine is 1,5-naphthalenediamine.

19. An interposer film according to claim 13 wherein the substrate comprises a coupling agent, a dispersant or a combination thereof.
